(19) United States
(12) Patent Application Publication
(10) Pub. No.: US 2026/0353695 A1
(43) Pub. Date: Nov. 5, 2026

(54) SEMICONDUCTOR DEVICE, METHOD OF MANUFACTURING SEMICONDUCTOR DEVICE, AND ELECTRONIC DEVICE

(71) Applicant: Fujitsu Limited, Kawasaki-shi (JP)

(72) Inventor: Atsushi YAMADA, Hiratsuka (JP)

(73) Assignee: Fujitsu Limited, Kawasaki-shi (JP)

(21) Appl. No.: 19/656,812

(22) Filed: Apr. 23, 2026

(30) Foreign Application Priority Data
May 2, 2025 (JP) 2025-076945

(51) Int. Cl. H10D 30/47; H10D 30/01; H10D 62/852

(52) U.S. Cl. CPC H10D 30/471; H10D 30/015; H10D 62/852

(57) ABSTRACT

A semiconductor device includes a buffer layer, a back barrier layer, a channel layer, and a barrier layer. The buffer layer contains AlGaN. The back barrier layer is disposed at a side of the buffer layer where a first surface of the buffer layer is located, and contains AlGaN. The channel layer is disposed at a side of the back barrier layer where a second surface of the back barrier layer opposite to the buffer layer is located, and contains AlGaN. The barrier layer is disposed at a side of the channel layer where a third surface of the channel layer opposite to the back barrier layer is located. The back barrier layer has an Al composition that increases in a direction from the buffer layer toward the channel layer.

### CROSS-REFERENCE TO RELATED APPLICATION

This application is based upon and claims the benefit of priority of the prior Japanese Patent Application No. 2025-076945, filed on May 2, 2025, the entire contents of which are incorporated herein by reference.

### FIELD

The embodiments discussed herein relate to a semiconductor device, a method of manufacturing a semiconductor device, and an electronic device.

### BACKGROUND

A semiconductor device is known that includes a GaN buffer layer, an AlGaN multilayer (back barrier layer) having an Al composition that varies along a depositing direction, a GaN channel layer, and an AlGaN barrier layer (see, for example, Japanese Laid-open Patent Publication No. 2015-135946).

### SUMMARY

In one aspect, there is provided a semiconductor device including: a buffer layer containing AlGaN; a back barrier layer disposed at a side of the buffer layer where a first surface of the buffer layer is located, the back barrier layer containing AlGaN; a channel layer disposed at a side of the back barrier layer where a second surface of the back barrier layer opposite to the buffer layer is located, the channel layer containing AlGaN; and a barrier layer disposed at a side of the channel layer where a third surface of the channel layer opposite to the back barrier layer is located, wherein the back barrier layer has an Al composition that increases in a direction from the buffer layer toward the channel layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a view for describing an example of a semiconductor device;

FIGS. 2A and 2B are views for describing an energy band structure and an electron concentration profile of the example of the semiconductor device;

FIG. 3 is a view for describing an example of a semiconductor device according to a first embodiment;

FIGS. 4A-4C are views each for describing the relationship between the Al composition and the spontaneous polarization of a nitride semiconductor;

FIGS. 5A and 5B illustrate an energy band structure and an electron concentration profile of the example of the semiconductor device according to the first embodiment;

FIGS. 6A and 6B are views (part 1) for describing an example of a method of manufacturing a semiconductor device according to a second embodiment;

FIGS. 7A and 7B are views (part 2) for describing the example of the method of manufacturing the semiconductor device according to the second embodiment;

FIG. 8 is a view for describing an example of a semiconductor package according to a third embodiment;

FIG. 9 is a view for describing an example of a power factor correction circuit according to a fourth embodiment;

FIG. 10 is a view for describing an example of a power supply device according to a fifth embodiment; and

FIG. 11 is a view for describing an example of an amplifier according to a sixth embodiment.

### DESCRIPTION OF EMBODIMENTS

In semiconductor devices including a high electron mobility transistor (HEMT), AlGaN may be used for its channel layer. However, conventional semiconductor devices in which AlGaN is used for their channel layers have sometimes failed to achieve high performance with excellent output characteristics.

First, an example of a semiconductor device will be described.

Semiconductor devices using nitride semiconductors have been developed as high-breakdown-voltage, high-power devices by utilizing characteristics such as a high saturation electron velocity and a wide band gap. For semiconductor devices using nitride semiconductors, many reports have been made on field effect transistors (FETs), for example, HEMTs. One type of HEMT uses aluminum gallium nitride (AlGaN) as a barrier layer and gallium nitride (GaN) as a channel layer. In such a HEMT, a high-concentration two-dimensional electron gas (2DEG) region is formed in the GaN channel layer due to spontaneous polarization of the AlGaN of the barrier layer and piezoelectric polarization generated in the AlGaN of the barrier layer due to strain caused by a lattice constant difference with the GaN of the channel layer. As a result, a high-power device is obtained.

In addition, regarding semiconductor devices using nitride semiconductors, in order to achieve further performance improvement, a semiconductor device has been proposed in which AlGaN, which is an ultra-wide band gap material, is used for the channel layer of a HEMT.

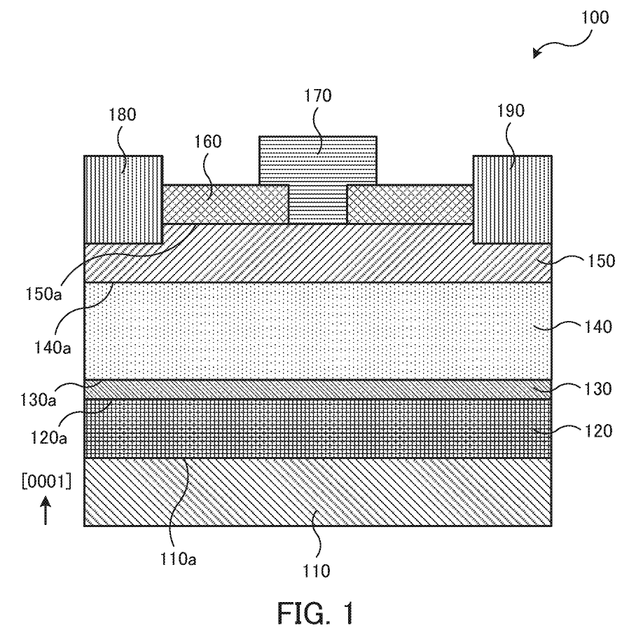

FIG. 1 is a view for describing an example of a semiconductor device. FIG. 1 schematically illustrates a cross-sectional view of a main part of the example of the semiconductor device.

A semiconductor device 100 illustrated in FIG. 1 is an example of a HEMT using a nitride semiconductor. The semiconductor device 100 includes a substrate 110, a buffer layer 120, a back barrier layer 130, a channel layer 140, a barrier layer 150, a passivation film 160, a gate electrode 170, a source electrode 180, and a drain electrode 190.

For example, aluminum nitride (AlN) is used for the substrate 110. One surface 110a of the substrate 110 is a group III polar surface, that is, a (0001) plane. The buffer layer 120 is disposed at a side of the substrate 110 where the surface 110a is located.

For example, AlGaN having a constant Al composition is used for the buffer layer 120. A surface 120a of the buffer layer 120 opposite to the substrate 110 is a group III polar surface, that is, a (0001) plane. The back barrier layer 130 is disposed at a side of the buffer layer 120 where the surface 120a is located.

For example, AlGaN having a constant Al composition is used for the back barrier layer 130. As an example, AlGaN having an Al composition lower than that of the buffer layer 120 is used for the back barrier layer 130. A surface 130a of the back barrier layer 130 opposite to the buffer layer 120 is a group III polar surface, that is, a (0001) plane. The channel layer 140 is disposed at a side of the back barrier layer 130 where the surface 130a is located.

For example, AlGaN having a constant Al composition is used for the channel layer 140. As an example, AlGaN having an Al composition higher than that of the back barrier layer 130 is used for the channel layer 140. A surface 140a of the channel layer 140 opposite to the back barrier layer 130 is a group III polar surface, that is, a (0001) plane. The barrier layer 150 is disposed at a side of the channel layer 140 where the surface 140a is located.

For example, AlN is used for the barrier layer 150. A surface 150a of the barrier layer 150 opposite to the channel layer 140 is a group III polar surface, that is, a (0001) plane. The gate electrode 170, the source electrode 180, the drain electrode 190, and the passivation film 160 are disposed at a side of the barrier layer 150 where the surface 150a is located.

The source electrode 180 and the drain electrode 190 are spaced apart from each other. The gate electrode 170 is disposed between the source electrode 180 and the drain electrode 190 and spaced apart from both of them. Predetermined metals are used for the gate electrode 170, the source electrode 180, and the drain electrode 190, respectively.

The passivation film 160 is disposed between the gate electrode 170 and the source electrode 180 and between the gate electrode 170 and the drain electrode 190. An insulating film such as SiN is used for the passivation film 160.

In the semiconductor device 100, a 2DEG region is formed in the channel layer 140 due to spontaneous polarization of the AlN of the barrier layer 150 and piezoelectric polarization generated in the AlN of the barrier layer 150 due to strain caused by a lattice constant difference between the AlN of the barrier layer 150 and the AlGaN of the channel layer 140.

During operation of the semiconductor device 100, for example, a voltage is applied such that the drain electrode 190 has a higher potential than the source electrode 180, and a predetermined voltage is applied to the gate electrode 170. The amount of charge in the 2DEG region of the channel layer 140, located directly below the gate electrode 170, is controlled by the field effect produced by the voltage applied to the gate electrode 170, thereby controlling the magnitude of an output drain current flowing between the source electrode 180 and the drain electrode 190. For example, the transistor function of the semiconductor device 100 is realized in this manner.

As described above, the semiconductor device 100 in which AlGaN is used for the channel layer 140 and AlN is used for the barrier layer 150 exhibits relatively small characteristic variations even at high temperature. Therefore, the semiconductor device 100 is expected to operate stably in a higher-temperature environment compared with a semiconductor device in which GaN is used for the channel layer 140 and AlGaN is used for the barrier layer 150.

In addition, in the semiconductor device 100, electron confinement is enhanced by a relatively large band offset between the AlGaN of the channel layer 140 and the AlN of the substrate 110 and the barrier layer 150. Therefore, an effect of suppressing occurrence of leakage current caused due to electron diffusion into a deep portion of the device is expected.

In the semiconductor device 100, the buffer layer 120 is disposed at the side of the substrate 110 where the channel layer 140 is located, and the back barrier layer 130 utilizing piezoelectric polarization is disposed between the buffer layer 120 and the channel layer 140, in expectation of an effect of further suppressing the occurrence of leakage current.

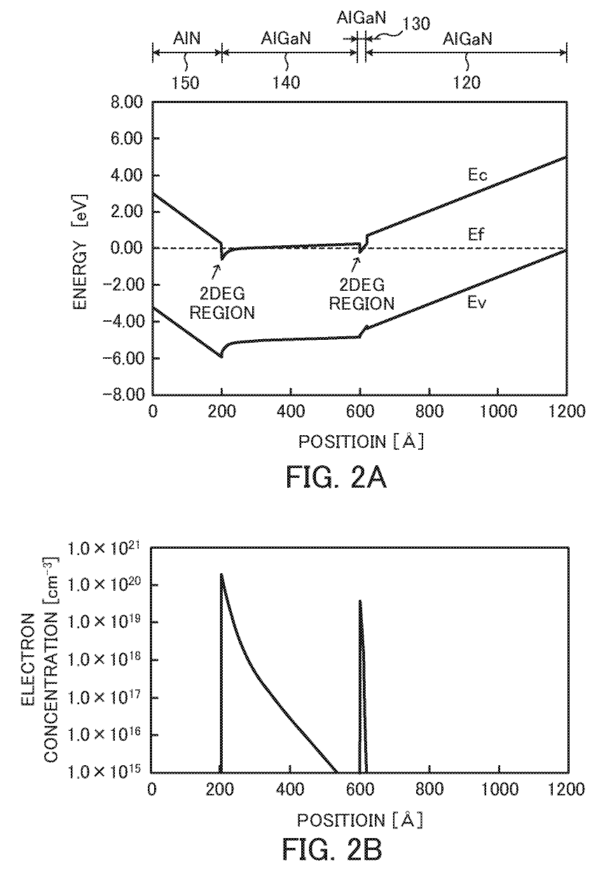

However, the semiconductor device 100 employing the back barrier layer 130 as described above may fail to suppress the leakage current sufficiently due to the strong polarization of the AlGaN-based semiconductor. This point will be described with reference to FIGS. 2A and 2B.

FIGS. 2A and 2B are views for describing an energy band structure and an electron concentration profile of the example of the semiconductor device. FIG. 2A represents the energy band structure of the example of the semiconductor device. In FIG. 2A, Ec denotes a conduction band, Ev denotes a valence band, and Ef denotes a Fermi level. FIG. 2B represents the electron concentration profile of the example of the semiconductor device.

For example, the semiconductor device 100 in which the back barrier layer 130 is disposed between the buffer layer 120 and the channel layer 140 and the barrier layer 150 is disposed at the side of the channel layer 140 opposite to the back barrier layer 130 has an energy band structure as illustrated in FIG. 2A. In this example, AlGaN having a constant Al composition is used for each of the buffer layer 120, the back barrier layer 130, and the channel layer 140. AlN is used for the barrier layer 150.

In the semiconductor device 100, as illustrated in FIG. 2A, the conduction band Ec of the AlGaN of the channel layer 140 in the vicinity of the AlN of the barrier layer 150 is at an energy lower than the Fermi level Ef, and a 2DEG region is formed in the channel layer 140 in the vicinity of the barrier layer 150.

In the semiconductor device 100, as illustrated in FIG. 2A, a 2DEG region is also formed in the AlGaN of the back barrier layer 130 disposed between the AlGaN of the channel layer 140 and the AlGaN of the buffer layer 120. This is because the strong polarization of the AlGaN-based semiconductor pulls the conduction band Ec of the AlGaN of the back barrier layer 130 down to an energy lower than the Fermi level Ef.

As a result, in the semiconductor device 100, as illustrated in FIG. 2B, in addition to the electron concentration profile corresponding to the 2DEG region formed in the channel layer 140, the electron concentration profile corresponding to the 2DEG region formed in the back barrier layer 130 is also observed.

The 2DEG region formed in the back barrier layer 130 is an undesired 2DEG region because it may cause a decrease in relative electron mobility within the channel layer 140 and may cause occurrence of leakage current through the back barrier layer 130. Therefore, with a device structure where such an undesired 2DEG region is formed in the back barrier layer 130, the semiconductor device 100 may fail to exhibit high performance with excellent output characteristics.

In view of the above circumstances, a high-performance semiconductor device is obtained by adopting a structure as described in the embodiments below.

### First Embodiment

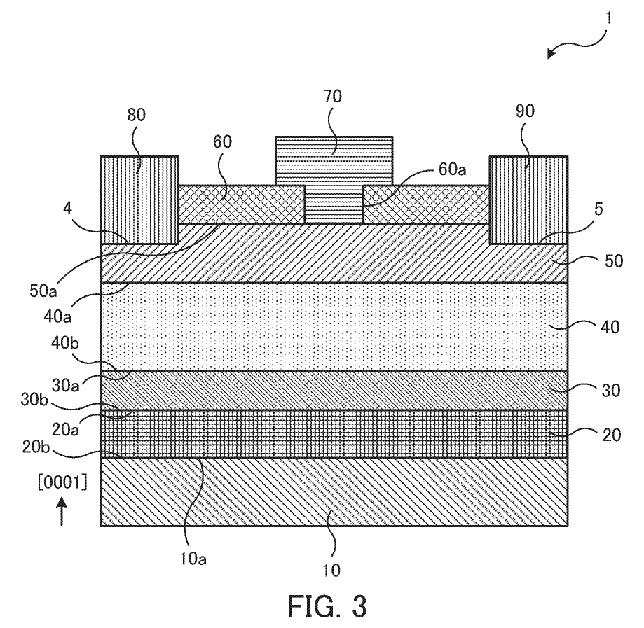

FIG. 3 is a view for describing an example of a semiconductor device according to a first embodiment. FIG. 3 schematically illustrates a cross-sectional view of a main part of the example of the semiconductor device.

A semiconductor device 1 illustrated in FIG. 3 is an example of a HEMT using a nitride semiconductor. The semiconductor device 1 includes a substrate 10, a buffer layer 20, a back barrier layer 30, a channel layer 40, a barrier layer 50, a passivation film 60, a gate electrode 70, a source electrode 80, and a drain electrode 90. In the semiconductor device 1, the channel layer 40 is also referred to as an “electron transit layer”, and the barrier layer 50 is also referred to as an “electron supply layer”. In the semiconductor device 1, a 2DEG region is formed in the channel layer 40 in the vicinity of the barrier layer 50.

For example, AlN is used for the substrate 10. The substrate 10 may be a single-layer substrate or a substrate having a multilayer structure. As an example, a single-layer AlN substrate is used as the substrate 10. Alternatively, a substrate having a multilayer structure including an underlying substrate and an AlN layer stacked thereon may be used as the substrate 10. In the case of the substrate 10 having such a multilayer structure, various substrates such as silicon carbide (SiC), sapphire, zinc oxide (ZnO), GaN, silicon (Si), diamond, gallium oxide (Ga₂O₃), scandium aluminum magnesium oxide (ScAlMgO₄), and AlN may be used as the underlying substrate.

The substrate 10 contains AlN at one surface 10a thereof. The AlN at the surface 10a of the substrate 10 is, for example, a part of a single-layer AlN substrate, an AlN layer stacked on an underlying substrate, or a part of such an AlN layer. The surface 10a of the substrate 10 is a group III polar surface, that is, a (0001) plane.

The buffer layer 20 is disposed at a side of the substrate 10 where the surface 10a is located. For example, AlGaN is used for the buffer layer 20. For example, AlGaN having a constant Al composition is used for the buffer layer 20. Alternatively, a multilayer structure including a plurality of AlGaN layers having different Al compositions may be used for the buffer layer 20. A surface 20a of the buffer layer 20 opposite to the substrate 10 is a group III polar surface, that is, a (0001) plane. The surface 20a of the buffer layer 20 opposite to the substrate 10 is also referred to as a “first surface”. In addition, a surface 20b of the buffer layer 20 facing toward the substrate 10, i.e., opposite to the back barrier layer 30 is also referred to as a “sixth surface”. It may also be said that the substrate 10 containing AlN, such as an AlN substrate, is disposed at a side of the buffer layer 20 where the surface 20b is located.

The back barrier layer 30 is disposed at a side of the buffer layer 20 where the surface 20a is located. For example, AlGaN is used for the back barrier layer 30. A surface 30a of the back barrier layer 30 opposite to the buffer layer 20 is a group III polar surface, that is, a (0001) plane. The channel layer 40 is disposed at a side of the back barrier layer 30 where the surface 30a is located. The surface 30a of the back barrier layer 30 opposite to the buffer layer 20 is also referred to as a “second surface”. A surface 30b of the back barrier layer 30 facing toward the buffer layer 20 is also referred to as a “fourth surface”.

As the AlGaN of the back barrier layer 30, AlGaN having an Al composition that increases in the direction from the buffer layer 20 or the substrate 10 toward the channel layer 40 is used. Hereinafter, such AlGaN having an Al composition that increases in the direction from the buffer layer 20 or the substrate 10 toward the channel layer 40 is also referred to as “composition-graded AlGaN”.

For example, in the composition-graded AlGaN of the back barrier layer 30, the Al composition at the surface 30b facing toward the buffer layer 20 is lower than the Al composition at the surface 20a of the buffer layer 20 facing toward the back barrier layer 30. For example, the Al composition at the surface 30b of the composition-graded AlGaN of the back barrier layer 30 is set lower than the Al composition at the surface 20a of the AlGaN of the buffer layer 20 by 0.1 or more. With the back barrier layer 30 having the composition-graded AlGaN in which the Al composition is set as above, a band offset occurs between the composition-graded AlGaN of the back barrier layer 30 and the AlGaN of the buffer layer 20. Thus, an energy barrier is formed in which the AlGaN of the buffer layer 20 has higher energy than the composition-graded AlGaN of the back barrier layer 30.

For example, the variation rate of the Al composition that increases in the direction from the buffer layer 20 toward the channel layer 40 in the composition-graded AlGaN of the back barrier layer 30 is preferably set to 0.002 nm⁻¹ or more, and more preferably set to 0.01 nm⁻¹ or more. In the semiconductor device 1, the composition-graded AlGaN set with such a variation rate is used for the back barrier layer 30. This allows the semiconductor device 1 to exhibit n-type semiconductivity as described later, which in turn suppresses the formation of a 2DEG region in the back barrier layer 30, a decrease in electron mobility, and occurrence of leakage current.

For example, the Al composition of the composition-graded AlGaN of the back barrier layer 30 may continuously increase in the direction from the buffer layer 20 toward the channel layer 40. Alternatively, the Al composition of the composition-graded AlGaN of the back barrier layer 30 may increase stepwise in the direction from the buffer layer 20 toward the channel layer 40.

The channel layer 40 is disposed at a side of the back barrier layer 30 where the surface 30a is located. For example, AlGaN is used for the channel layer 40. For example, AlGaN having a constant Al composition is used for the channel layer 40. Alternatively, a multilayer structure including a plurality of AlGaN layers having different Al compositions may be used for the channel layer 40. A surface 40a of the channel layer 40 opposite to the back barrier layer 30 is a group III polar surface, that is, a (0001) plane. The barrier layer 50 is disposed at a side of the channel layer 40 where the surface 40a is located. The surface 40a of the channel layer 40 opposite to the back barrier layer 30 is also referred to as a “third surface”. A surface 40b of the channel layer 40 facing toward the back barrier layer 30 is also referred to as a “fifth surface”.

The Al composition of the AlGaN of the channel layer 40 may be set based on the Al composition of the composition-graded AlGaN of the back barrier layer 30. For example, the Al composition at the surface 40b of the channel layer 40 facing toward the back barrier layer 30 is set such that the difference from the Al composition at the surface 30a of the back barrier layer 30 facing toward the channel layer 40 is 0.1 or less. By setting such an Al composition difference, it is possible to suppress the occurrence of a relatively large band offset and lattice constant difference between the AlGaN of the channel layer 40 and the composition-graded AlGaN of the back barrier layer 30. This suppresses the formation of a 2DEG region in the back barrier layer 30 due to polarization of the channel layer 40.

The barrier layer 50 is disposed at a side of the channel layer 40 where the surface 40a is located. In order to form a 2DEG region in the channel layer 40 in the vicinity of the barrier layer 50, a nitride semiconductor having a band gap larger than that of the AlGaN of the channel layer 40 is used for the barrier layer 50. A surface 50a of the barrier layer 50 opposite to the channel layer 40 is a group III polar surface, that is, a (0001) plane.

For the barrier layer 50, a nitride semiconductor containing Al (hereinafter, also referred to as “Al-containing nitride semiconductor”) is used as a nitride semiconductor having a band gap larger than that of the AlGaN of the channel layer 40. For example, AlN is used for the Al-containing nitride semiconductor of the barrier layer 50. Other than AlN, AlGaN having an Al composition higher than that of the AlGaN of the channel layer 40, for example, by 0.1 or more may be used for the barrier layer 50. For the barrier layer 50, an Al-containing nitride semiconductor such as indium aluminum gallium nitride (InAlGaN) or indium aluminum nitride (InAlN) may be used as long as it has a band gap larger than that of the AlGaN of the channel layer 40.

AlN, AlGaN, InAlGaN, and InAlN are each a type of Al-containing nitride semiconductor. For the barrier layer 50, a single-layer Al-containing nitride semiconductor may be used, or an Al-containing nitride semiconductor in which a plurality of layers are stacked may be used.

The gate electrode 70, the source electrode 80, and the drain electrode 90 are disposed at a side of the barrier layer 50 where the surface 50a is located, which is opposite to the channel layer 40. The surface 50a of the barrier layer 50 opposite to the channel layer 40 is also referred to as a “seventh surface”.

The source electrode 80 and the drain electrode 90 are spaced apart from each other. For example, the source electrode 80 and the drain electrode 90 are provided in a recess 4 and a recess 5 formed in the surface 50a of the barrier layer 50, respectively. Metals such as tantalum (Ta) and aluminum (Al) are used for the source electrode 80 and the drain electrode 90. One or more kinds of metals may be used for the source electrode 80 and the drain electrode 90. The source electrode 80 and the drain electrode 90 are provided to function as ohmic electrodes.

In each portion of the barrier layer 50 corresponding to regions to which the source electrode 80 and the drain electrode 90 are connected or in portions of the barrier layer 50 and the channel layer 40, a regrown layer formed using a nitride semiconductor containing an n-type impurity (hereinafter, also referred to as an “n-type nitride semiconductor”) may be provided as a contact layer.

The gate electrode 70 is disposed between the source electrode 80 and the drain electrode 90 and spaced apart from both of them. For example, the gate electrode 70 is provided in an opening 60a formed in the passivation film 60. A metal such as nickel (Ni) or gold (Au) is used for the gate electrode 70. One or more kinds of metals may be used for the gate electrode 70. For example, the gate electrode 70 is provided to function as a Schottky electrode.

A cap layer (not illustrated) formed using a doped or non-doped nitride semiconductor may be interposed between the gate electrode 70 and the barrier layer 50. For example, for charge modulation in the 2DEG region formed in the channel layer 40, a nitride semiconductor doped with a p-type impurity (hereinafter also referred to as a “p-type nitride semiconductor”) may be provided as the cap layer. Alternatively, in order to protect the buffer layer 20, the back barrier layer 30, the channel layer 40, the barrier layer 50, and others from the outside, a non-doped nitride semiconductor may be provided as the cap layer.

In addition, the gate electrode 70 may have a metal insulator semiconductor (MIS) gate structure in which a gate insulating film (not illustrated) formed using an oxide, a nitride, an oxynitride, or the like is interposed between the gate electrode 70 and the barrier layer 50.

The passivation film 60 is disposed at a side of the barrier layer 50 where the surface 50a is located, and between the gate electrode 70 and the source electrode 80 and between the gate electrode 70 and the drain electrode 90. For the passivation film 60, for example, an oxide, a nitride, or an oxynitride containing at least one of Si, Al, hafnium (Hf), zirconium (Zr), titanium (Ti), Ta, and tungsten (W) is used. As an example, silicon nitride (SiN) is used for the passivation film 60.

In the semiconductor device 1 having the above-described structure, the buffer layer 20, the back barrier layer 30, the channel layer 40, and the barrier layer 50 are grown at the side of the substrate 10 where the surface 10a is located, by metal-organic chemical vapor deposition (MOCVD, or metal-organic vapor phase epitaxy (MOVPE)) or molecular beam epitaxy (MBE), for example.

Note that the lattice constant of the a-axis orthogonal to the c-axis ( direction) of AlGaN is relatively close to the lattice constant of the a-axis orthogonal to the c-axis of AlN. The lattice constant of the a-axis of AlGaN approaches the lattice constant of the a-axis of AlN as the Al composition thereof increases. AlGaN grown over AlN using the MOVPE or the like is relatively easily lattice-matched to an underlying AlN, which means that a lattice mismatch with the underlying AlN is relatively unlikely to occur.

In the semiconductor device 1, an Al-containing nitride semiconductor that is likely to be lattice-matched to the AlN of the substrate 10 is used for each of the buffer layer 20, the back barrier layer 30, the channel layer 40, and the barrier layer 50.

In the semiconductor device 1, for example, the Al composition of the AlGaN of the buffer layer 20 grown over the substrate 10 is adjusted so that the AlGaN of the buffer layer 20 is lattice—matched to the AlN of the substrate 10. Furthermore, for example, the Al composition, the variation rate of the Al composition, and the average Al composition of the composition-graded AlGaN of the back barrier layer 30 grown over the buffer layer 20 are adjusted so that the composition-graded AlGaN of the back barrier layer 30 is lattice-matched to the AlGaN of the buffer layer 20. Furthermore, for example, the Al composition of the AlGaN of the channel layer 40 grown over the back barrier layer 30 is adjusted so that the AlGaN of the channel layer 40 is lattice-matched to the composition-graded AlGaN of the back barrier layer 30. Furthermore, for example, the Al composition of the Al-containing nitride semiconductor of the barrier layer 50 grown over the channel layer 40 is adjusted so that the Al-containing nitride semiconductor of the barrier layer 50 is lattice-matched to the AlGaN of the channel layer 40.

In addition to the Al compositions, the thickness in the c-axis direction of each of the Al-containing nitride semiconductors used for the buffer layer 20, the back barrier layer 30, the channel layer 40, and the barrier layer 50 may be further adjusted so as to achieve lattice matching to the AlN of the substrate 10.

The lattice matching of each of the buffer layer 20, the back barrier layer 30, the channel layer 40, and the barrier layer 50 to the substrate 10 may be evaluated using an X-ray diffractometer or the like.

For example, in order to improve the breakdown voltage of the semiconductor device 1, the Al compositions of the AlGaN of the buffer layer 20, the back barrier layer 30, and the channel layer 40 are preferably set to 0.5 or more. In order to improve the electron mobility within the channel layer 40, the Al composition of the Al-containing nitride semiconductor of the barrier layer 50 is preferably set to 0.7 or more. Furthermore, from the viewpoint of the lattice matching to the AlN of the substrate 10, the Al compositions of the buffer layer 20, the back barrier layer 30, the channel layer 40, and the barrier layer 50 are preferably as close to 1.0 as possible. From the viewpoint of sufficiently improving the performance of the semiconductor device 1, the buffer layer 20, the back barrier layer 30, the channel layer 40, and the barrier layer 50 are preferably provided such that the average Al composition thereof is 0.5 or more.

AlN is used for the substrate 10 over which the buffer layer 20, the back barrier layer 30, the channel layer 40, and the barrier layer 50 are grown. As the substrate 10, a single-layer AlN substrate or a substrate in which an AlN layer is stacked on an underlying substrate is used.

Note that, in the case where the AlGaN of the buffer layer 20, the composition-graded AlGaN of the back barrier layer 30, the AlGaN of the channel layer 40, and the Al-containing nitride semiconductor of the barrier layer 50 are grown over another substrate, for example, a SiC substrate, the following may occur. Specifically, dislocations are likely to occur in the channel layer 40, and if the dislocation density exceeds 1 × 10⁸ cm⁻², there is a risk that the electron concentration and electron mobility may decrease due to the dislocations. The decrease in the electron concentration and the electron mobility due to the dislocations leads to the performance degradation of the semiconductor device 1.

In contrast, the use of the substrate 10 containing AlN as described above makes it possible to suppress the dislocation density in the channel layer 40 to 1 × 10⁸ cm⁻² or less. The use of the substrate 10 containing AlN having good crystal quality makes it possible to further suppress the dislocation density in the channel layer 40 to 1 × 10⁶ cm⁻² or less. Therefore, by using the substrate 10 containing AlN to suppress the dislocation density in the channel layer 40 to 1 × 10⁸ cm⁻² or less, it becomes possible to suppress the performance degradation of the semiconductor device 1.

Even with the substrate 10 containing AlN, the dislocation density in the channel layer 40 may fail to be suppressed to less than a certain value, for example, less than 1 × 10⁴ cm⁻², due to the crystal quality of the substrate 10 or the multilayer growth process of the Al-containing nitride semiconductor over the substrate 10. Even in such a case, the use of the substrate 10 containing AlN makes it possible to suppress the dislocation density in the channel layer 40 within a certain range, for example, within a range between 1 × 10⁴ cm⁻² and 1 × 10⁸ cm⁻², inclusive.

In addition, if a large number of dislocations occur inside the channel layer 40 during the growth of the channel layer 40, impurities such as carbon and oxygen are likely to be incorporated in the vicinity of the dislocations. In the case where the AlGaN of the buffer layer 20, the composition-graded AlGaN of the back barrier layer 30, the AlGaN of the channel layer 40, and the Al-containing nitride semiconductor of the barrier layer 50 are grown over another substrate, for example, a SiC substrate, instead of the substrate 10 containing AlN, the following may occur. Specifically, dislocations are likely to occur in the channel layer 40, and impurities such as carbon and oxygen are more likely to be incorporated into the channel layer 40 accordingly, and if the carbon concentration or the oxygen concentration in the channel layer 40 exceeds 1 × 10¹⁹ cm⁻³, there is a risk that the electron mobility or the like decreases. The decrease in the electron mobility or the like due to the incorporation of carbon or oxygen leads to, for example, the performance degradation of the semiconductor device 1.

In contrast, the use of the substrate 10 containing AlN as described above makes it possible to suppress dislocations in the channel layer 40, suppress the carbon concentration in the channel layer 40 to 1 × 10¹⁹ cm⁻³ or less, and suppress the oxygen concentration in the channel layer 40 to 1 × 10¹⁹ cm⁻³ or less. The use of the substrate 10 containing AlN having good crystal quality makes it possible to further suppress the carbon concentration in the channel layer 40 to 1 × 10¹⁸ cm⁻³ or less, and further suppress the oxygen concentration in the channel layer 40 to 1 × 10¹⁸ cm⁻³ or less. By using the substrate 10 containing AlN and suppressing the carbon or oxygen concentration in the channel layer 40 to 1 × 10¹⁹ cm⁻³ or less, it becomes possible to suppress the performance degradation of the semiconductor device 1.

Even with the substrate 10 containing AlN, the carbon concentration or the oxygen concentration in the channel layer 40 may fail to be suppressed to less than a certain value, for example, less than 1 × 10¹⁴ cm⁻³, due to the crystal quality of the substrate 10 or the multilayer growth process of the Al-containing nitride semiconductor over the substrate 10. Even in such a case, the use of the substrate 10 including AlN makes it possible to suppress the carbon concentration in the channel layer 40 within a certain range, for example, within a range between 1 × 10¹⁴ cm⁻³ and 1 × 10¹⁹ cm⁻³, inclusive. In addition, the use of the substrate 10 containing AlN makes it possible to suppress the oxygen concentration in the channel layer 40 within a certain range, for example, within a range between 1 × 10¹⁴ cm⁻³ and 1 × 10¹⁹ cm⁻³, inclusive.

In the semiconductor device 1 (FIG. 3) having the above-described structure, a predetermined voltage is applied to each of the source electrode 80 and the drain electrode 90, and the gate electrode 70, whereby the semiconductor device 1 operates as a transistor. During operation of the semiconductor device 1, for example, a voltage is applied such that the drain electrode 90 has a higher potential than the source electrode 80, and a predetermined voltage is applied to the gate electrode 70. The amount of charge in the 2DEG region of the channel layer 40, located directly below the gate electrode 70, is controlled by the field effect produced by the voltage applied to the gate electrode 70, thereby controlling the magnitude of an output drain current flowing between the source electrode 80 and the drain electrode 90. For example, the transistor function of the semiconductor device 1 is realized in this manner.

Next, the back barrier layer 30 using composition-graded AlGaN will be described.

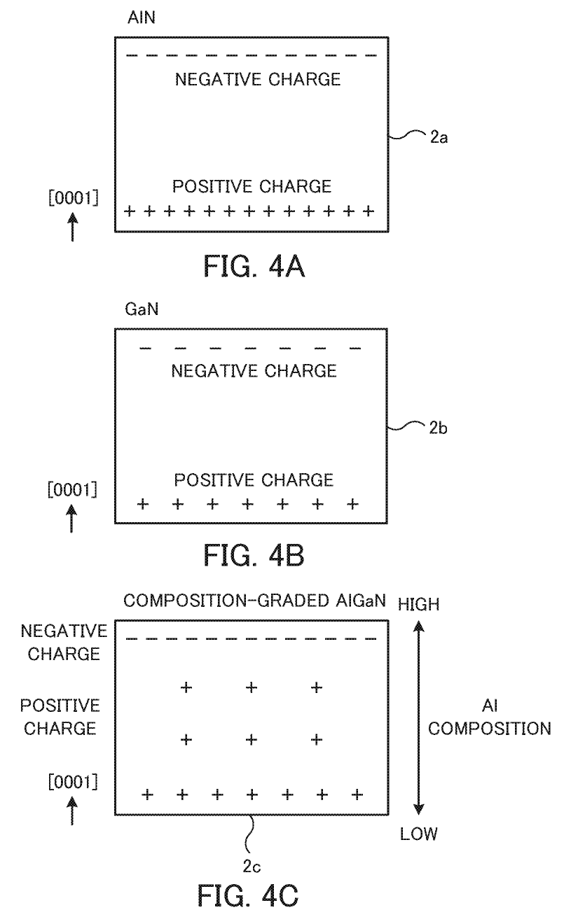

FIGS. 4A-4C are views each for describing the relationship between the Al composition and the spontaneous polarization of a nitride semiconductor. FIG. 4A schematically illustrates the spontaneous polarization in AlN. FIG. 4B schematically illustrates the spontaneous polarization in GaN. FIG. 4C schematically illustrates the spontaneous polarization in composition-graded AlGaN.

Nitride semiconductors have spontaneous polarization along the direction (c-axis). AlN has stronger spontaneous polarization than GaN. For example, let the direction be the upward direction as illustrated in FIGS. 4A and 4B. Regarding polarization charge, negative charge (indicated by “-”) is induced at the upper end sides of an AlN layer 2a and a GaN layer 2b, while positive charge (indicated by “+”) is induced at the lower end sides thereof. Since AlN has stronger spontaneous polarization than GaN, the amount of charge induced in the AlN layer 2a is larger than that induced in the GaN layer 2b.

AlGaN, which is a mixed crystal, has an amount of charge that is intermediate between those of AlN and GaN, depending on its Al composition. In the case of a composition-graded AlGaN layer 2c, the total amount of charge within the composition-graded AlGaN layer 2c is ±0. However, letting the direction be the upward direction, the amounts of polarization at the upper end and the lower end are different from each other, and therefore a charge deficiency arises in the middle. Accordingly, as illustrated in FIG. 4C, positive fixed charges are three-dimensionally distributed within the composition-graded AlGaN layer 2c. A semiconductor in which positive fixed charges are three-dimensionally distributed in this manner exhibits the properties of an n-type semiconductor (hereinafter, also referred to as “n-type semiconductivity” or “n-type characteristics”), similar to a semiconductor doped with an n-type impurity.

In the semiconductor device 1 illustrated in FIG. 3, the back barrier layer 30 is made of composition-graded AlGaN in which n-type semiconductivity is exhibited by increasing the Al composition toward one surface ((0001) plane) of the layer.

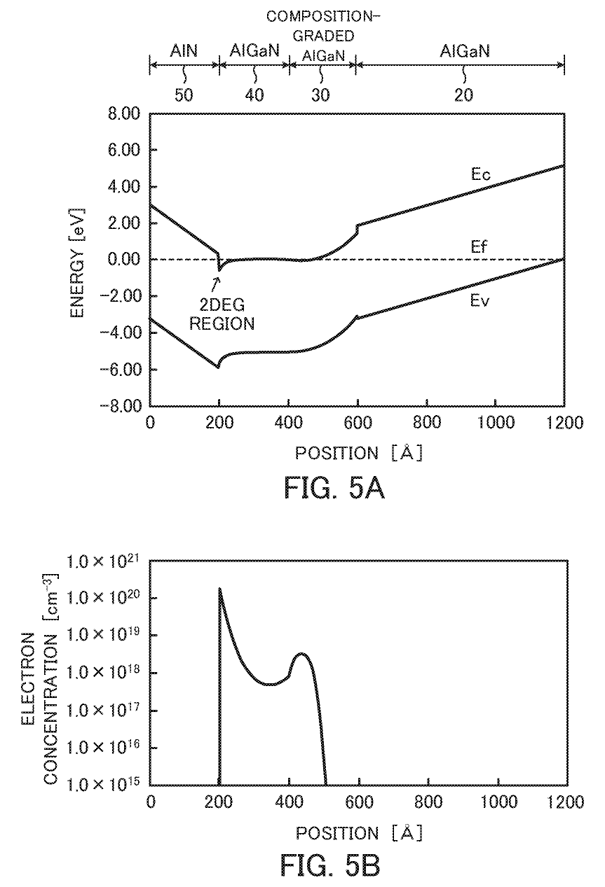

FIGS. 5A and 5B are views for describing an energy band structure and an electron concentration profile of the example of the semiconductor device according to the first embodiment. FIG. 5A illustrates an energy band structure of the example of the semiconductor device. In FIG. 5A, Ec represents a conduction band, Ev represents a valence band, and Ef represents a Fermi level. FIG. 5B illustrates an electron concentration profile of the example of the semiconductor device.

In the case where AlGaN is used for the buffer layer 20, composition-graded AlGaN is used for the back barrier layer 30, AlGaN is used for the channel layer 40, and AlN is used for the barrier layer 50, the semiconductor device 1 has an energy band structure as illustrated in FIG. 5A. Since the conduction band Ec of the AlGaN of the channel layer 40 becomes lower in energy than the Fermi level Ef, a 2DEG region is formed in the channel layer 40 in the vicinity of the barrier layer 50.

In the semiconductor device 1, the composition-graded AlGaN of the back barrier layer 30 is disposed between the AlGaN of the buffer layer 20 and the AlGaN of the channel layer 40. As described above, the composition-graded AlGaN of the back barrier layer 30 has an Al composition that increases in the direction from the buffer layer 20 toward the channel layer 40, thereby exhibiting n-type semiconductivity. The use of the composition-graded AlGaN having n-type semiconductivity for the back barrier layer 30 pulls the conduction band Ec of the back barrier layer 30 down to the low energy side.

As a result, as illustrated in FIG. 5A, the conduction band Ec of the AlGaN of the channel layer 40 joined to the composition-graded AlGaN of the back barrier layer 30 is pulled down to the low energy side as compared with the energy of the conduction band Ec before being joined to the composition-graded AlGaN. In addition, as illustrated in FIG. 5A, an energy barrier is formed between the composition-graded AlGaN of the back barrier layer 30 and the AlGaN of the buffer layer 20 so that the AlGaN of the buffer layer 20 has higher energy. In the semiconductor device 1, the conduction band Ec of the composition-graded AlGaN of the back barrier layer 30 is prevented from becoming lower in energy than the Fermi level Ef, which leads to suppressing formation of an undesired 2DEG region in the back barrier layer 30.

In the semiconductor device 1, for example, as described above, the difference between the Al composition at the surface 30a of the composition-graded AlGaN of the back barrier layer 30, at the side where the channel layer 40 is located, and the Al composition at the surface 40b of the AlGaN of the channel layer 40, at the side where the back barrier layer 30 is located, is set to 0.1 or less. In addition, the Al composition at the surface 30b of the composition-graded AlGaN of the back barrier layer 30, at the side where the buffer layer 20 is located, is set lower than the Al composition at the surface 20a of the buffer layer 20, at the side where the back barrier layer 30 is located, for example, by 0.1 or more. In the semiconductor device 1, such Al composition conditions are adopted, and the energy band structure as illustrated in FIG. 5A is obtained.

The semiconductor device 1 has the energy band structure as illustrated in FIG. 5A, and formation of a 2DEG region in the back barrier layer 30 is suppressed. Thus, the semiconductor device 1 has an electron concentration profile in which electrons spread within the channel layer 40 and further spread toward the back barrier layer 30, as illustrated in FIG. 5B. In the semiconductor device 1, formation of an undesired 2DEG region in the back barrier layer 30, for example, the formation of the 2DEG region as illustrated in FIG. 2B is suppressed, and a decrease in relative electron mobility within the channel layer 40 and occurrence of leakage current through the back barrier layer 30 are suppressed.

Since the decrease in electron mobility within the channel layer 40 and the occurrence of leakage current through the back barrier layer 30 are suppressed, the semiconductor device 1 exhibits improved output characteristics. By using composition-graded AlGaN as described above for the back barrier layer 30, the semiconductor device 1 exhibiting high performance and excellent output characteristics is obtained, in which the decrease in electron mobility and the occurrence of leakage current are suppressed.

### Second Embodiment

An example of a method of manufacturing a semiconductor device will be described as a second embodiment. Here, a method of manufacturing the semiconductor device 1 (FIG. 3) described in the first embodiment is taken as an example.

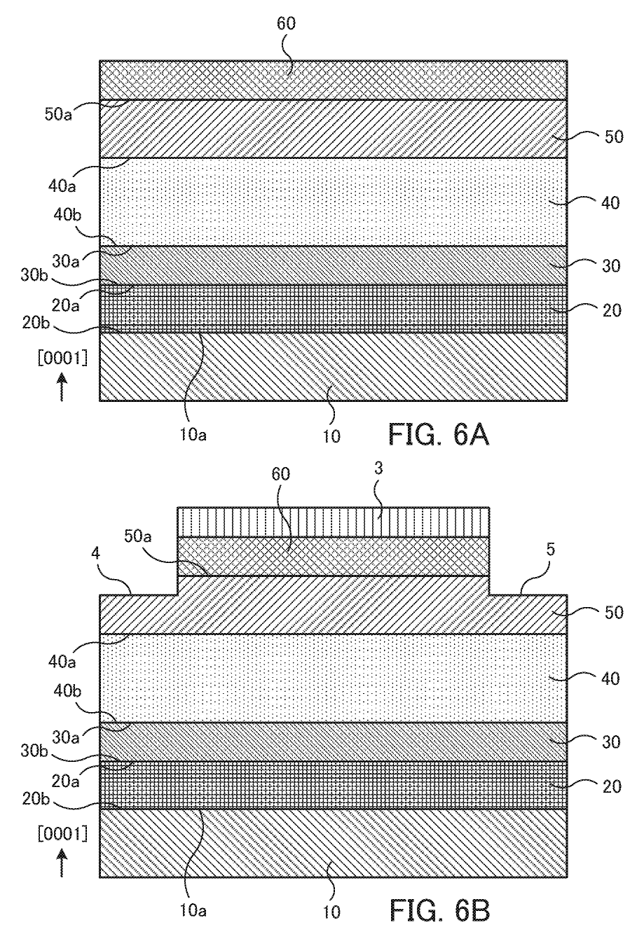

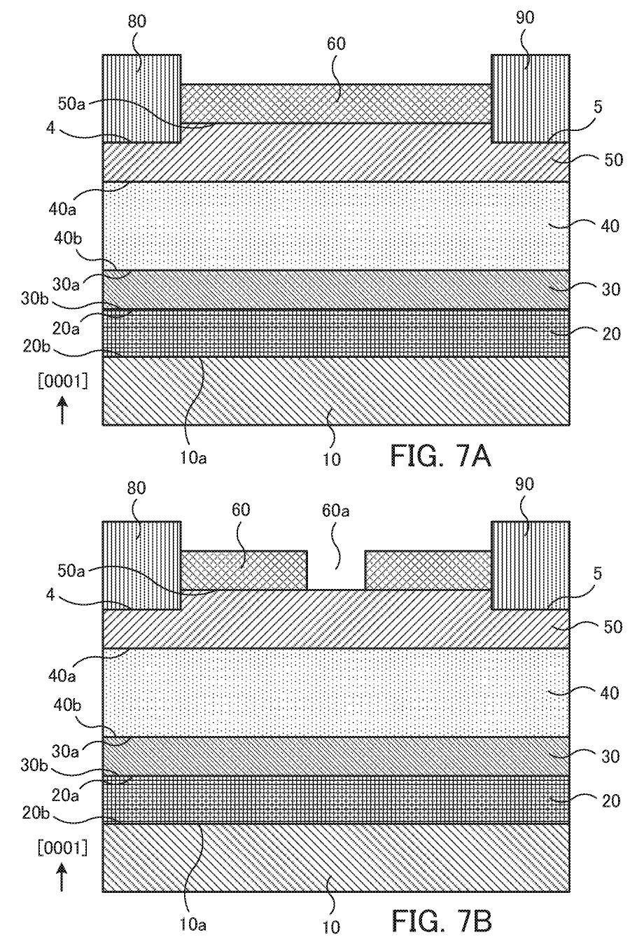

FIGS. 6A, 6B, 7A, and 7B are views for describing an example of the method of manufacturing the semiconductor device according to the second embodiment. FIG. 6A schematically illustrates a cross-sectional view of a main part of an example of a semiconductor growth and passivation film formation step. FIG. 6B schematically illustrates a cross-sectional view of a main part of an example of a recess formation step. FIG. 7A schematically illustrates a cross-sectional view of a main part of an example of a source electrode and drain electrode formation step. FIG. 7B schematically illustrates a cross-sectional view of a main part of an example of an opening formation step.

First, as illustrated in FIG. 6A, the buffer layer 20, the back barrier layer 30, the channel layer 40, and the barrier layer 50 are sequentially grown over the substrate 10 using the MOVPE method. For example, an AlN substrate is used as the substrate 10. For example, Alₓ₁Ga₁₋ₓ₁N (0.3 ≤ x1 ≤ 1.0) having a thickness of 800 nm is grown as the buffer layer 20 at the side of the substrate 10 where the surface 10a is located. For example, composition-graded AlₐGa₁₋ₐN (0.3 ≤ a < 1.0) having a thickness of 20 nm in which the Al composition increases in the direction from the buffer layer 20 toward the channel layer 40 is grown as the back barrier layer 30 at the side of the buffer layer 20 where the surface 20a is located. For example, Alₓ₂Ga₁₋ₓ₂N (0.3 ≤ x2 < 1.0) having a thickness of 20 nm is grown as the channel layer 40 at the side of the back barrier layer 30 where the surface 30a is located. For example, In_{y3}Alₓ₃Ga_{1-x3-y3}N (0.3 ≤ x3 ≤ 1.0, 0 ≤ y3 ≤ 0.2) having a thickness of 20 nm is grown as the barrier layer 50 at the side of the channel layer 40 where the surface 40a is located.

The composition-graded AlₐGa₁₋ₐN of the back barrier layer 30 is grown such that the Al composition (a1) at the side thereof close to the buffer layer 20 is low and the Al composition (a2) at the side thereof close to the channel layer 40 is high (a1<a2). The Al composition a of the back barrier layer 30 may increase monotonously or stepwise in the direction from the buffer layer 20 toward the channel layer 40. The variation rate of the Al composition a of the back barrier layer 30 is set to, for example, preferably 0.002 nm⁻¹ or more, and more preferably 0.01 nm⁻¹ or more. In order to improve the breakdown voltage, the Al composition a of the back barrier layer 30 is set such that the Al composition (a1) at the side thereof close to the buffer layer 20 and the Al composition (a2) at the side thereof close to the channel layer 40 are preferably 0.3 or more, and more preferably 0.5 or more.

In order to improve the breakdown voltage, the Al composition x1 of the buffer layer 20, the Al composition x2 of the channel layer 40, and the Al composition x3 of the barrier layer 50 are each preferably set to 0.3 or more, more preferably 0.5 or more. Furthermore, in order to improve the electron mobility within the channel layer 40 in the vicinity of the barrier layer 50, the Al composition x3 of the barrier layer 50 is preferably set to 0.6 or more, and more preferably 0.7 or more.

From the viewpoint of sufficiently improving the performance of the semiconductor device 1, the average Al composition of the buffer layer 20, the back barrier layer 30, the channel layer 40, and the barrier layer 50 is preferably set to 0.5 or more.

In the growth of a nitride semiconductor using the MOVPE method, a mixed gas of trimethylaluminum (TMAl) as an Al source and ammonia (NH₃) is used for the growth of AlN. For the growth of AlGaN, a mixed gas of TMAl as an Al source, trimethylgallium (TMGa) as a gallium (Ga) source, and NH₃ is used. For the growth of InAlGaN, a mixed gas of trimethylindium (TMIn) as an In source, TMAl as an Al source, TMGa as a Ga source, and NH₃ is used. For the growth of InAlN, a mixed gas of TMIn as an In source, TMAl as an Al source, and NH₃ is used. The supply and stoppage (switching) of source materials such as TMAl, TMGa, and TMIn and the flow rates during supply (mixing ratios with other source materials) are appropriately set according to the nitride semiconductor to be grown. Hydrogen or nitrogen is used as a carrier gas.

After the growth of the buffer layer 20, the back barrier layer 30, the channel layer 40, and the barrier layer 50 using the MOVPE method, the passivation film 60 is formed at the side of the barrier layer 50 where the surface 50a is located, as illustrated in FIG. 6A. For example, the passivation film 60 having a thickness in a range of 2 nm to 500 nm, for example, a thickness of 100 nm is formed using a plasma chemical vapor deposition (CVD) method. Instead of the plasma CVD method, atomic layer deposition (ALD) or sputtering may be used to form the passivation film 60. For example, an oxide, a nitride, or an oxynitride containing at least one of Si, Al, Hf, Zr, Ti, Ta, and W is used for the passivation film 60. For example, SiN is formed as the passivation film 60.

After the passivation film 60 is formed, an element isolation region (not illustrated) is formed. For example, a resist pattern (not illustrated) having an opening in a region where the element isolation region is to be formed is formed using photolithography. Then, using the formed resist pattern as a mask, dry etching using a chlorine (Cl)-based gas or ion implantation of argon (Ar) or the like is performed on the nitride semiconductor layer in the opening, thereby forming the element isolation region. After the element isolation region is formed, the resist pattern used as the mask is removed using an organic solvent or the like.

Subsequently, as illustrated in FIG. 6B, a surface protective film 3 is formed on the passivation film 60. For example, the surface protective film 3 is formed using a plasma CVD method. Alternatively, the surface protective film 3 may be formed using ALD, sputtering, or the like. For the surface protective film 3, for example, an oxide, a nitride, or an oxynitride containing at least one of Si, Al, Hf, Zr, Ti, Ta, and W is used. For example, silicon oxide (SiO₂) is formed as the surface protective film 3.

After the surface protective film 3 is formed, the recess 4 and the recess 5 are formed in the barrier layer 50 in the regions where the source electrode 80 and the drain electrode 90 are to be formed, as illustrated in FIG. 6B. For example, a resist pattern (not illustrated) having openings in regions where the source electrode 80 and the drain electrode 90 are to be formed is formed using photolithography. Then, using the formed resist pattern as a mask, dry etching using a fluorine (F)-based gas is performed on the surface protective film 3 and the passivation film 60 in the openings. Further, dry etching using a Cl-based gas is performed on the barrier layer 50 exposed by the dry etching of the passivation film 60. Thereby, the recess 4 and the recess 5 are formed in parts of the barrier layer 50. After the recess 4 and the recess 5 are formed, the resist pattern used as the mask is removed using an organic solvent or the like.

Subsequently, as illustrated in FIG. 7A, the source electrode 80 is formed in one recess 4 of the barrier layer 50, and the drain electrode 90 is formed in the other recess 5 of the barrier layer 50. For example, a resist pattern (not illustrated) having openings in regions corresponding to the recess 4 and the recess 5 of the barrier layer 50 is formed using photolithography. Next, metals are deposited on the resist pattern and in the openings thereof using a vacuum deposition method. As an example, Ta having a thickness of 20 nm is deposited, and Al having a thickness of 200 nm is deposited thereon. After the deposition of the metals, the resist pattern is removed together with the metals deposited thereon using a lift-off technique. Thus, the source electrode 80 and the drain electrode 90 are formed in the recess 4 and the recess 5 of the barrier layer 50, respectively. Thereafter, heat treatment (alloying treatment) is performed in a nitrogen atmosphere at a temperature in a range of 400°C to 1000°C, for example, at 550°C, thereby establishing ohmic characteristics of the source electrode 80 and the drain electrode 90. Thus, the source electrode 80 and the drain electrode 90 that function as ohmic electrodes are formed.

After the source electrode 80 and the drain electrode 90 are formed, the surface protective film 3 is removed. As a result, the state illustrated in FIG. 7A is obtained.

Subsequently, as illustrated in FIG. 7B, the passivation film 60 is partially removed in a region where the gate electrode 70 is to be formed, thereby forming an opening 60a extending to the barrier layer 50. For example, a resist pattern (not illustrated) having an opening in a region where the gate electrode 70 is to be formed is formed using photolithography. Then, using the formed resist pattern as a mask, dry etching using an F-based gas is performed on the passivation film 60 in the opening. Alternatively, the passivation film 60 may be etched by wet etching using hydrofluoric acid, buffered hydrofluoric acid, or the like. The opening 60a is formed in a part of the passivation film 60 using predetermined etching. After the opening 60a is formed, the resist pattern used as the mask is removed using an organic solvent or the like.

After the opening 60a is formed in the passivation film 60, the gate electrode 70 is formed in the opening 60a as illustrated in FIG. 3. For example, a resist pattern (not illustrated) having an opening in a region where the gate electrode 70 is to be formed is formed using photolithography. Next, metals are deposited on the resist pattern and in the opening using a vacuum deposition method. As an example, Ni having a thickness of 30 nm is deposited, and Au having a thickness of 400 nm is deposited thereon. After the deposition of the metals, the resist pattern is removed together with the metals deposited thereon by a lift-off technique. Thus, the gate electrode 70 that functions as a Schottky electrode is formed in the opening 60a of the passivation film 60. For example, as illustrated in FIG. 3, the gate electrode 70 is formed not only in the opening 60a but also on a part of the upper surface of the passivation film 60 outside the opening 60a.

Through the above-described steps, the semiconductor device 1 having the structure illustrated in FIG. 3 is manufactured.

The semiconductor device 1 is provided with the back barrier layer 30 using composition-graded AlGaN in which the Al composition increases in the direction from the buffer layer 20 toward the channel layer 40 to thereby exhibit n-type semiconductivity. The use of such composition-graded AlGaN for the back barrier layer 30 suppresses formation of a 2DEG region in the back barrier layer 30. As a result, a decrease in electron mobility within the channel layer 40 and occurrence of leakage current through the back barrier layer 30 are suppressed. Therefore, the semiconductor device 1 exhibiting high performance and excellent output characteristics is obtained, in which the decrease in electron mobility and the occurrence of leakage current are suppressed.

The types of metals and the layer structure used for the gate electrode 70, the source electrode 80, and the drain electrode 90 of the semiconductor device 1 are not limited to the above example, and the method of forming them is also not limited to the above example. Each of the gate electrode 70, the source electrode 80, and the drain electrode 90 may be formed of a single-layer metal or a metal having a multilayer structure. In forming the source electrode 80 and the drain electrode 90, the heat treatment as described above is not necessarily performed as long as ohmic characteristics are realized by the formation (vapor deposition) of these metals. Further, in forming the gate electrode 70, additional heat treatment may be performed after its metals are formed.

In the above example, an AlN substrate is used as the substrate 10. Alternatively, a substrate 10 having a structure in which an AlN layer is stacked on any type of underlying substrate may be used as the substrate 10. The substrate 10 may be a semi-insulating substrate or a electrically conductive substrate.

In the above example, the gate electrode 70 that functions as a Schottky electrode is provided in the semiconductor device 1. Note that a gate insulating film formed of an oxide, a nitride, an oxynitride, or the like may be disposed between the gate electrode 70 and the barrier layer 50, thereby forming an MIS-type gate structure. Further, a cap layer formed of a doped (for example, p-type) or non-doped nitride semiconductor may be interposed between the gate electrode 70 and the barrier layer 50.

In the above example, the source electrode 80 and the drain electrode 90 are respectively provided in the recess 4 and the recess 5 formed in the barrier layer 50 in the steps described with reference to FIGS. 6B and 7A. Alternatively, the source electrode 80 and the drain electrode 90 may be disposed on the barrier layer 50 without forming the recesses 4 and 5. Alternatively, the recess 4 and the recess 5 may be formed so as to penetrate through the barrier layer 50 and reach the inside of the channel layer 40, n-type nitride semiconductors may be regrown therein as a contact layer, and the source electrode 80 and the drain electrode 90 may be formed thereon.

The first and second embodiments have been described above.

The semiconductor device 1 described above or the like may be applied to various electronic devices. As an example, the following describes cases where the semiconductor device 1 or the like having the above-described structure is applied to a semiconductor package, a power factor correction circuit, a power supply device, and an amplifier.

### Third Embodiment

Here, an application example of the semiconductor device 1 or the like having the above-described structure to a semiconductor package will be described as a third embodiment.

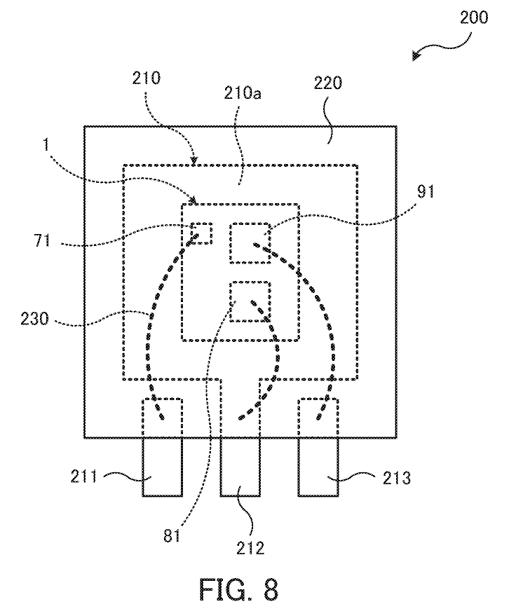

FIG. 8 is a view for describing an example of a semiconductor package according to a third embodiment. FIG. 8 schematically illustrates a plan view of a main part of the example of the semiconductor package.

A semiconductor package 200 illustrated in FIG. 8 is an example of a discrete package. The semiconductor package 200 includes, for example, the semiconductor device 1 (FIG. 3) described in the first embodiment, a lead frame 210 on which the semiconductor device 1 is mounted, and a resin 220 that encapsulates them.

For example, the semiconductor device 1 is mounted on a die pad 210a of the lead frame 210 using a die attach material or the like (not illustrated). The semiconductor device 1 additionally includes a pad 71 connected to the gate electrode 70, a pad 81 connected to the source electrode 80, and a pad 91 connected to the drain electrode 90. The pad 71, the pad 81, and the pad 91 are respectively connected to a gate lead 211, a source lead 212, and a drain lead 213 of the lead frame 210 using wires 230 made of Au, Al, or the like. The lead frame 210, the semiconductor device 1 mounted on the lead frame 210, and the wire 230 connecting the lead frame 210 and the semiconductor device 1 are encapsulated with the resin 220 such that each of the gate lead 211, the source lead 212, and the drain lead 213 is partially exposed.

An external connection electrode connected to the source electrode 80 may be provided on a surface of the semiconductor device 1 opposite to the surface on which the pad 71 connected to the gate electrode 70 and the pad 91 connected to the drain electrode 90 are disposed. The external connection electrode may be connected to the die pad 210a connected to the source lead 212, using an electrically conductive bonding material such as solder.

For example, by using the semiconductor device 1 as described in the first embodiment, the semiconductor package 200 is obtained.

As described earlier, the semiconductor device 1 is provided with the back barrier layer 30 using composition-graded AlGaN in which the Al composition increases in the direction from the buffer layer 20 toward the channel layer 40 to thereby exhibit n-type semiconductivity. This suppresses formation of a 2DEG region in the back barrier layer 30. Therefore, the semiconductor device 1 exhibiting high performance and excellent output characteristics is obtained, in which a decrease in electron mobility within the channel layer 40 and occurrence of leakage current through the back barrier layer 30 are suppressed. By using this semiconductor device 1, the high-performance semiconductor package 200 is obtained.

In the above example, the semiconductor device 1 is used. Alternatively, the semiconductor package 200 may be similarly obtained using another semiconductor device including the back barrier layer 30.

### Fourth Embodiment

Here, an application example of the semiconductor device 1 or the like having the above-described structure to a power factor correction circuit will be described as a fourth embodiment.

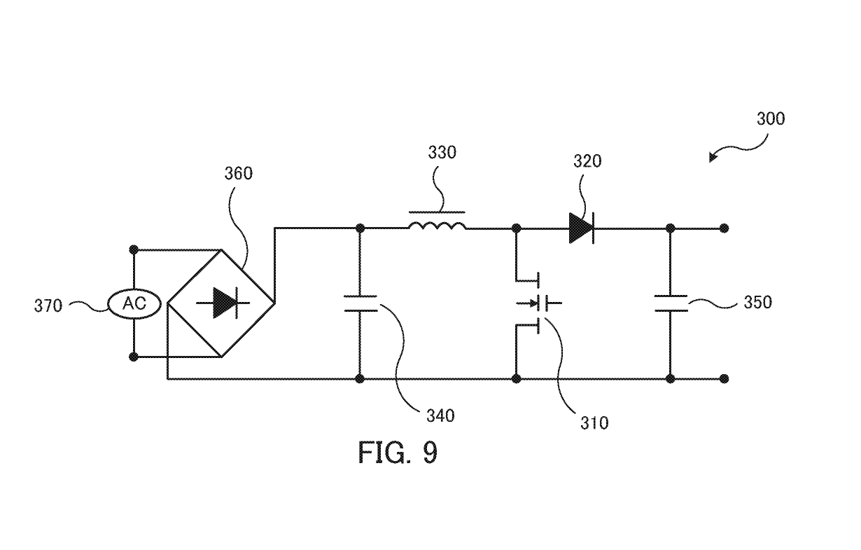

FIG. 9 is a view for describing an example of a power factor correction circuit according to the fourth embodiment. FIG. 9 is an equivalent circuit diagram of an example of the power factor correction circuit.

A power factor correction (PFC) circuit 300 illustrated in FIG. 9 includes a switching element 310, a diode 320, a choke coil 330, a capacitor 340, a capacitor 350, a diode bridge 360, and an AC power supply 370 (AC).

In the PFC circuit 300, the drain electrode of the switching element 310 is connected to the anode terminal of the diode 320 and to one terminal of the choke coil 330. The source electrode of the switching element 310 is connected to one terminal of the capacitor 340 and to one terminal of the capacitor 350. The other terminal of the capacitor 340 and the other terminal of the choke coil 330 are connected to each other. The other terminal of the capacitor 350 and the cathode terminal of the diode 320 are connected to each other. A gate driver is connected to the gate electrode of the switching element 310. The AC power supply 370 is connected between both terminals of the capacitor 340 via the diode bridge 360, and a DC power supply (DC) is derived from across both terminals of the capacitor 350.

For example, the semiconductor device 1 or the like is used for the switching element 310 of the PFC circuit 300 having such a configuration.

As described earlier, the semiconductor device 1 or the like is provided with the back barrier layer 30 using composition-graded AlGaN in which the Al composition increases in the direction from the buffer layer 20 toward the channel layer 40 to thereby exhibit n-type semiconductivity. This suppresses formation of a 2DEG region in the back barrier layer 30. Therefore, the semiconductor device 1 or the like exhibiting high performance and excellent output characteristics is obtained, in which a decrease in electron mobility within the channel layer 40 and occurrence of leakage current through the back barrier layer 30 are suppressed. By using this semiconductor device or the like, the high-performance PFC circuit 300 is obtained.

### Fifth Embodiment

Here, an application example of the semiconductor device 1 or the like having the above-described structure to a power supply device will be described as a fifth embodiment.

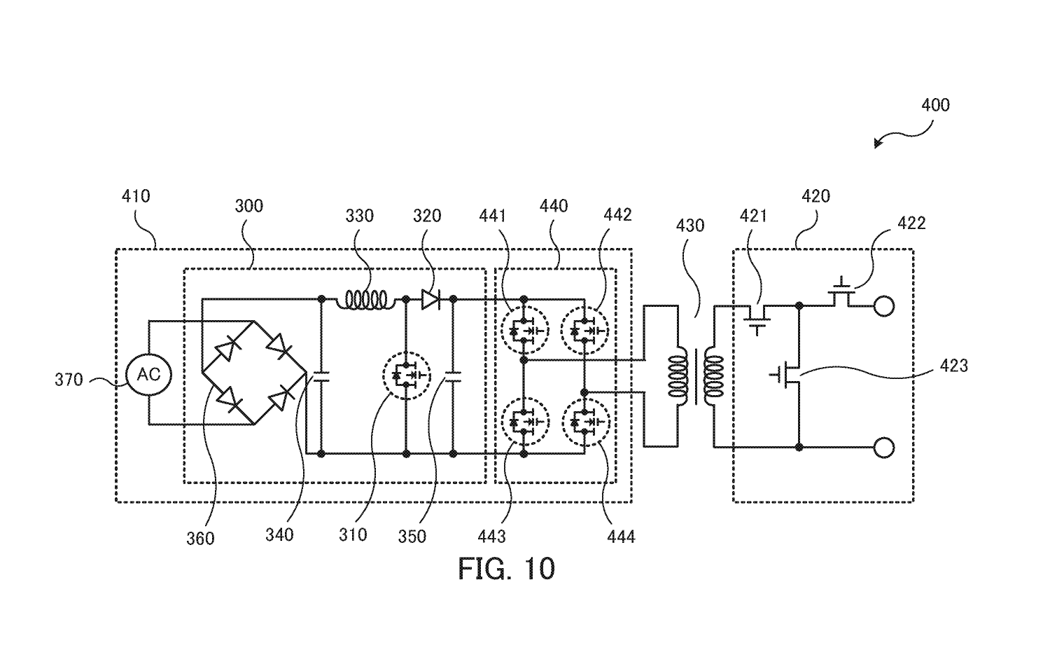

FIG. 10 is a view for describing an example of a power supply device according to the fifth embodiment. FIG. 10 is an equivalent circuit diagram of an example of the power supply device.

A power supply device 400 illustrated in FIG. 10 includes a primary circuit 410, a secondary circuit 420, and a transformer 430 disposed between the primary circuit 410 and the secondary circuit 420.

The primary circuit 410 includes the PFC circuit 300 as described in the fourth embodiment, and an inverter circuit, for example, a full-bridge inverter circuit 440 connected between both terminals of the capacitor 350 of the PFC circuit 300. The full-bridge inverter circuit 440 includes a plurality of switching elements, for example, four switching elements 441, 442, 443, and 444.

The secondary circuit 420 includes a plurality of switching elements, for example, three switching elements 421, 422, and 423.

For example, in the power supply device 400 having such a configuration, the semiconductor device 1 or the like is used for the switching element 310 of the PFC circuit 300 included in the primary circuit 410 and the switching elements 441 to 444 of the full-bridge inverter circuit 440. For example, MIS-type FETs using Si are used for the switching elements 421 to 423 of the secondary circuit 420 in the power supply device 400.

As described earlier, the semiconductor device 1 or the like is provided with the back barrier layer 30 using composition-graded AlGaN in which the Al composition increases in the direction from the buffer layer 20 toward the channel layer 40 to thereby exhibit n-type semiconductivity. This suppresses formation of a 2DEG region in the back barrier layer 30. Therefore, the semiconductor device 1 or the like exhibiting high performance and excellent output characteristics is obtained, in which a decrease in electron mobility within the channel layer 40 and occurrence of leakage current through the back barrier layer 30 are suppressed. By using this semiconductor device 1 or the like, the high-performance power supply device 400 is obtained.

### Sixth Embodiment

Here, an application example of the semiconductor device 1 or the like having the above-described structure to an amplifier will be described as a sixth embodiment.

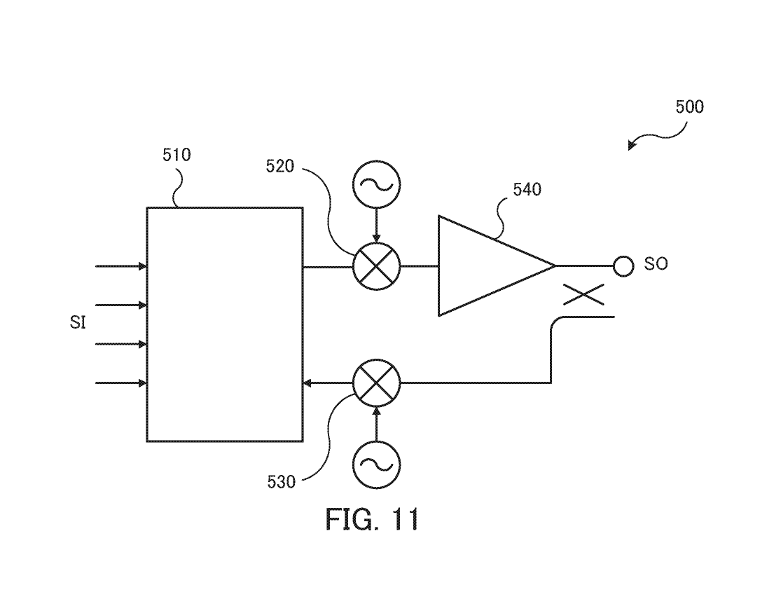

FIG. 11 is a view for describing an example of an amplifier according to the sixth embodiment. FIG. 11 is an equivalent circuit diagram of an example of the amplifier.

An amplifier 500 illustrated in FIG. 11 includes a digital predistortion circuit 510, a mixer 520, a mixer 530, and a power amplifier 540.

The digital predistortion circuit 510 compensates for nonlinear distortion of an input signal. The mixer 520 mixes an input signal SI, in which nonlinear distortion has been compensated for, with an AC signal. The power amplifier 540 amplifies a signal obtained by mixing the input signal SI with the AC signal. In the amplifier 500, for example, by switching a switch, an output signal SO may be mixed with the AC signal by the mixer 530 and sent to the digital predistortion circuit 510. The amplifier 500 may be used as a high-frequency amplifier or a high-power amplifier.

The above-described semiconductor device 1 or the like is used for the power amplifier 540 in the amplifier 500 having such a configuration.

As described earlier, the semiconductor device 1 or the like is provided with the back barrier layer 30 using composition-graded AlGaN in which the Al composition increases in the direction from the buffer layer 20 toward the channel layer 40 to thereby exhibit n-type semiconductivity. This suppresses formation of a 2DEG region in the back barrier layer 30. Therefore, the semiconductor device 1 or the like exhibiting high performance and excellent output characteristics is obtained, in which a decrease in electron mobility within the channel layer 40 and occurrence of leakage current through the back barrier layer 30 are suppressed. By using this semiconductor device 1 or the like, the high-performance amplifier 500 is obtained.

Various electronic devices (such as the semiconductor package 200, the PFC circuit 300, the power supply device 400, and the amplifier 500 described in the third to sixth embodiments) to which the above-described semiconductor device 1 or the like is applied may be mounted in various electronic apparatuses or electronic devices. For example, they may be mounted in various electronic apparatuses or electronic devices such as computers (personal computers, supercomputers, servers, and others), smartphones, mobile phones, tablet terminals, sensors, cameras, audio devices, measurement apparatuses, inspection apparatuses, manufacturing apparatuses, transmitters, receivers, and radar apparatuses.

In one aspect, a high-performance semiconductor device is obtained.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a buffer layer containing AlGaN;
a back barrier layer disposed at a side of the buffer layer where a first surface of the buffer layer is located, the back barrier layer containing AlGaN;
a channel layer disposed at a side of the back barrier layer where a second surface of the back barrier layer opposite to the buffer layer is located, the channel layer containing AlGaN; and
a barrier layer disposed at a side of the channel layer where a third surface of the channel layer opposite to the back barrier layer is located,
wherein the back barrier layer has an Al composition that increases in a direction from the buffer layer toward the channel layer.

2. The semiconductor device according to claim 1, wherein an Al composition at a fourth surface of the back barrier layer facing toward the buffer layer is lower than an Al composition at the first surface of the buffer layer.

3. The semiconductor device according to claim 2, wherein the Al composition at the fourth surface of the back barrier layer is lower than the Al composition at the first surface of the buffer layer by 0.1 or more.

4. The semiconductor device according to claim 1, wherein a difference between an Al composition at the second surface of the back barrier layer and an Al composition at a fifth surface of the channel layer facing toward the back barrier layer is 0.1 or less.

5. The semiconductor device according to claim 1, wherein an average Al composition of the buffer layer, the back barrier layer, the channel layer, and the barrier layer is 0.5 or more.

6. The semiconductor device according to claim 1, wherein a variation rate of the Al composition of the back barrier layer in the direction from the buffer layer toward the channel layer is 0.002 nm⁻¹ or more.

7. The semiconductor device according to claim 1, wherein the Al composition of the back barrier layer increases continuously in the direction from the buffer layer toward the channel layer.

8. The semiconductor device according to claim 1, wherein the Al composition of the back barrier layer increases stepwise in the direction from the buffer layer toward the channel layer.

9. The semiconductor device according to claim 1, further comprising a substrate at a side of the buffer layer where a sixth surface of the buffer layer opposite to the back barrier layer is located, the substrate containing AlN.

10. The semiconductor device according to claim 9, wherein the substrate is an AlN substrate.

11. The semiconductor device according to claim 9, wherein the buffer layer, the back barrier layer, the channel layer, and the barrier layer are lattice-matched to the substrate.

12. The semiconductor device according to claim 1, further comprising:
a source electrode and a drain electrode disposed at a side of the barrier layer where a seventh surface of the barrier layer opposite to the channel layer is located, the source electrode and drain electrode being spaced apart from each other; and
a gate electrode disposed at the side of the barrier layer where the seventh surface is located, the gate electrode being located between the source electrode and the drain electrode and spaced apart from each of the source electrode and the drain electrode.

13. The semiconductor device according to claim 1, wherein the channel layer has a dislocation density of 1 × 10⁸ cm⁻² or less.

14. The semiconductor device according to claim 1, wherein the channel layer has a carbon concentration of 1 × 10¹⁹ cm⁻³ or less.

15. The semiconductor device according to claim 1, wherein the channel layer has an oxygen concentration of 1 × 10¹⁹ cm⁻³ or less.

16. A method of manufacturing a semiconductor device, the method comprising:
forming a back barrier layer at a side of a buffer layer where a first surface of the buffer layer is located, the back barrier layer containing AlGaN, the buffer layer containing AlGaN;
forming a channel layer at a side of the back barrier layer where a second surface of the back barrier layer opposite to the buffer layer is located, the channel layer containing AlGaN; and
forming a barrier layer at a side of the channel layer where a third surface of the channel layer opposite to the back barrier layer is located,
wherein the forming of the back barrier layer includes forming the back barrier layer such that an Al composition of the back barrier layer increases in a direction from the buffer layer toward the channel layer.

17. An electronic device comprising:
a semiconductor device including:
a buffer layer containing AlGaN,
a back barrier layer disposed at a side of the buffer layer where a first surface of the buffer layer is located, the back barrier layer containing AlGaN,
a channel layer disposed at a side of the back barrier layer where a second surface of the back barrier layer opposite to the buffer layer is located, the channel layer containing AlGaN, and
a barrier layer disposed at a side of the channel layer where a third surface of the channel layer opposite to the back barrier layer is located,
wherein the back barrier layer has an Al composition that increases in a direction from the buffer layer toward the channel layer.
